(19) United States
(12) Patent Application Publication
(10) Pub. No.: US 2026/0164595 A1
(43) Pub. Date: Jun. 11, 2026

(54) SELF-CHECKOUT SYSTEM WITH THERMAL MANAGEMENT

(71) Applicant: TOSHIBA GLOBAL COMMERCE SOLUTIONS, INC., Durham, NC (US)

(72) Inventors: Brad M. JOHNSON, Raleigh, NC (US); William L. DUNGAN, Cary, NC (US)

(21) Appl. No.: 18/976,082

(22) Filed: Dec. 10, 2024

(51) Int. Cl. H05K 7/20; G06F 1/20; H05K 5/00

(52) U.S. Cl. CPC H05K 7/20145; G06F 1/20; H05K 5/0018; H05K 7/20209; H05K 7/20972

(57) ABSTRACT

A self-checkout system is provided. In one aspect, a self-checkout system includes a housing having a base and a back panel extending from the base. The self-checkout system also includes an interactive module mounted to the back panel, the interactive module having a display screen and a curved deflector arranged at a top side of the display screen. An airflow channel is formed between the display screen and the back panel so that air within the airflow channel and heated by the display screen travels upwards along the airflow channel and is deflected away from the display screen by the curved deflector.

### BACKGROUND

Many retail stores offer buyers the option to purchase items at self-service kiosks. Self-service kiosks have become desirable to both buyers and retailers. For buyers, the kiosks offer reduced wait times as compared to using a cashier lane. Retailers can benefit from increased checkout efficiency. During a checkout transaction, a buyer can scan product barcodes for each product and can place them on a platform to be weighed and/or monitored during the transaction. A display screen can provide helpful information to the buyer, such as the cost of the items scanned, whether an item is on sale or discounted, a weight of an item, etc.

### BRIEF DESCRIPTION OF THE DRAWINGS

FIG. 1A depicts a perspective view of a self-checkout system, according to one or more aspects of the present disclosure.

FIG. 1B depicts a side view of the self-checkout system of FIG. 1A.

FIG. 1C depicts a side view of a self-checkout system, according to one or more aspects of the present disclosure.

FIG. 1D depicts a side view of a self-checkout system, according to one or more aspects of the present disclosure.

FIG. 1E depicts a schematic side view of a self-checkout system, according to one or more aspects of the present disclosure.

FIG. 1F depicts a schematic side view of a self-checkout system, according to one or more aspects of the present disclosure.

FIG. 1G depicts a side view of a checkout area having a plurality of self-checkout systems, according to one or more aspects of the present disclosure.

FIG. 2A depicts a perspective view of a self-checkout system, according to one or more aspects of the present disclosure.

FIG. 2B depicts a side view of the self-checkout system of FIG. 2A.

FIG. 3 is a block diagram of a computing system for a self-checkout system, according to one or more aspects of the present disclosure.

### DETAILED DESCRIPTION

Self-checkout systems can include display screens that provide helpful information to a user during a transaction, such as the cost of scanned items, whether an item is on sale or discounted, a weight of an item, etc. Along with the display screen, self-checkout systems can include components that produce heat during operation, such as processors, power supplies, scanners, printers, etc. The performance and life of the display screen and the noted components can be negatively affected or shortened if their thermal load is not properly managed.

Aspects disclosed herein are directed to self-checkout systems with thermal management features for managing the thermal load of a display screen and other components that produce heat during operation. In this way, the performance and life of the display screen and other components can be enhanced or lengthened. In one example aspect, a self-checkout system can include a housing having a base and a back panel extending vertically from the base. An interactive module can be mounted to the back panel. The interactive module can include a display screen and a control unit, which can include processing elements that implement operation of the self-checkout system. An airflow channel is defined between the display screen and the back panel. A curved deflector can be arranged at the top end of the display screen. In this way, when air heated by the display screen and components of the control unit travels upwards along the airflow channel, the heated air can be deflected by the curved deflector away from the display screen and the control unit. The curved deflector can deflect the heated air so that the heated air is expelled toward a back of the self-checkout system. This can move the heated air away from the display screen and components of the control unit, which can increase their performance and service lives, but can also move the heated air away from a user present at the self-checkout system. In at least one example, a fan can be selectively activated to move the heated air within the airflow channel, e.g., upwards so that the curved deflector deflects and expels the heated air from the airflow channel. In some aspects, depending on one or more conditions, the fan can be controlled to move heated air downward along the airflow channel, e.g., so that a curved bottom surface of the back panel directs the heated air toward a front of the self-checkout system. According, in at least one example, the air can be forced upward or downward along the airflow channel, depending on one or more conditions.

In addition, the self-checkout systems disclosed herein can include architecture that enables the center of gravity of a system to be centrally located, which can advantageously: reduce the stress on the back panel and the mounting bracket coupling the interactive module with the back panel; can make the self-checkout system less susceptible to tipping, e.g., in the event the self-checkout system is subject to an impact event; can provide users with a more solid feel when providing an input to the display screen; and can make the design more compact. In one aspect, the back panel of a self-checkout system can be arranged to have a shorter transverse length than the base, and consequently, the housing can define a cutout. The display screen can be arranged in the cutout and overhanging, at least in part, the base. Moreover, the bottom end of the back panel can include a curved bottom surface that transitions the front wall of the back panel between a vertical orientation and a horizontal orientation. This radiused bottom end of the back panel can couple with the base at the forward side of the base. The radiused bottom end of the back panel can increase the transverse length of the back panel, which can provide structural rigidity to the back panel and can reduce stress concentrations within the housing.

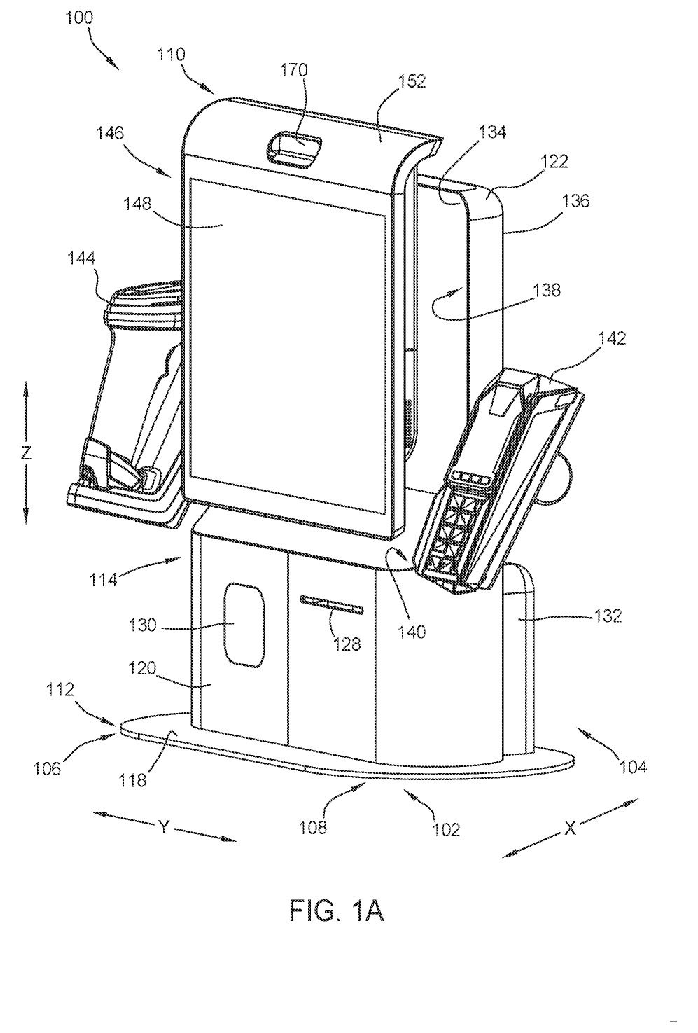

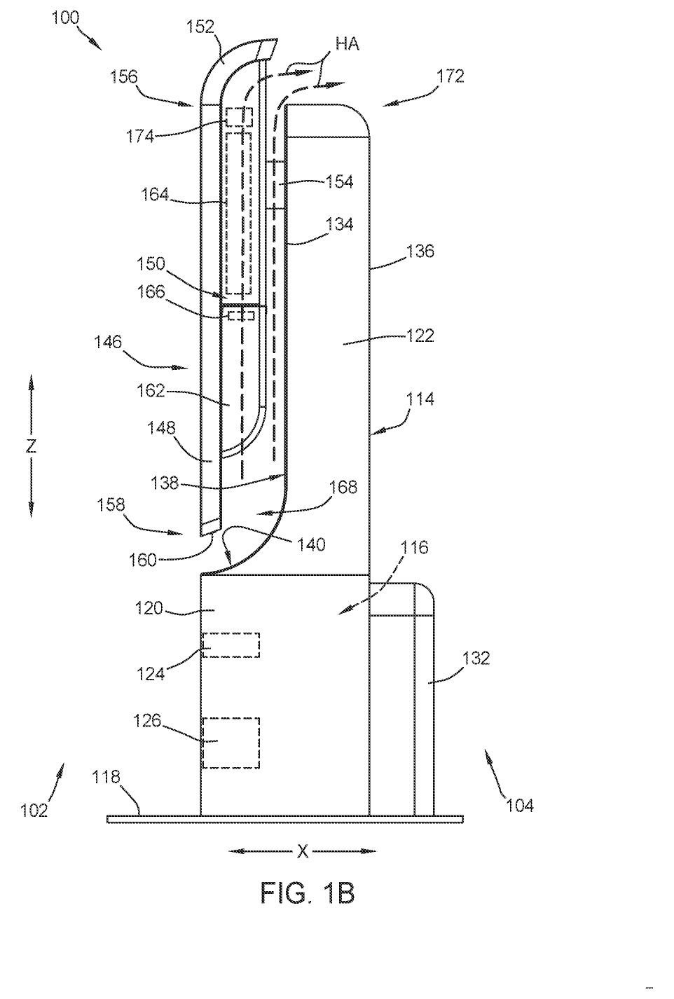

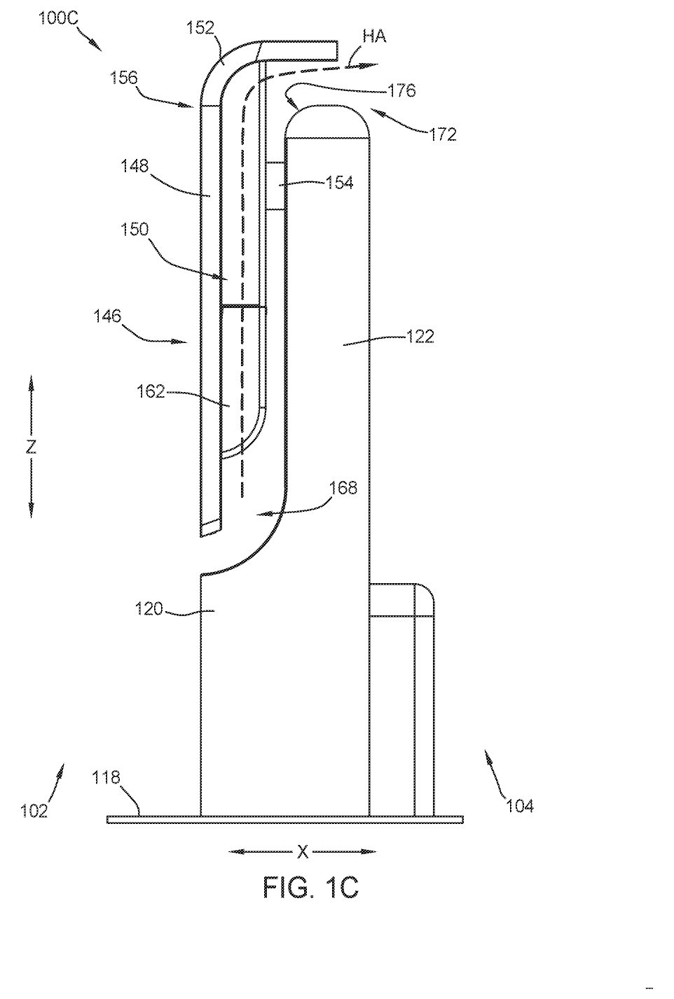

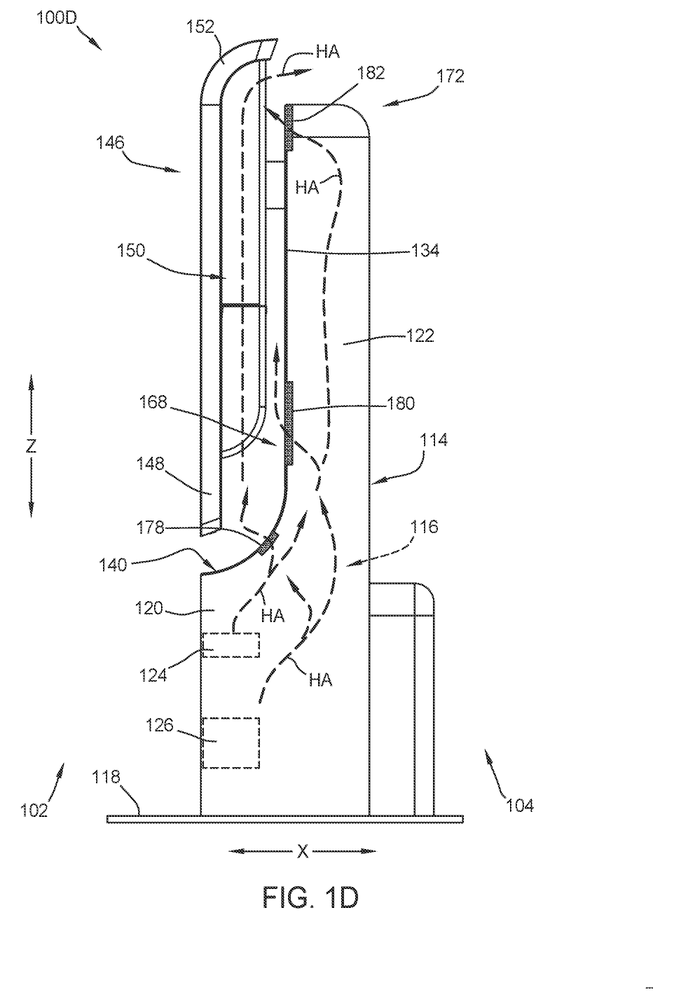

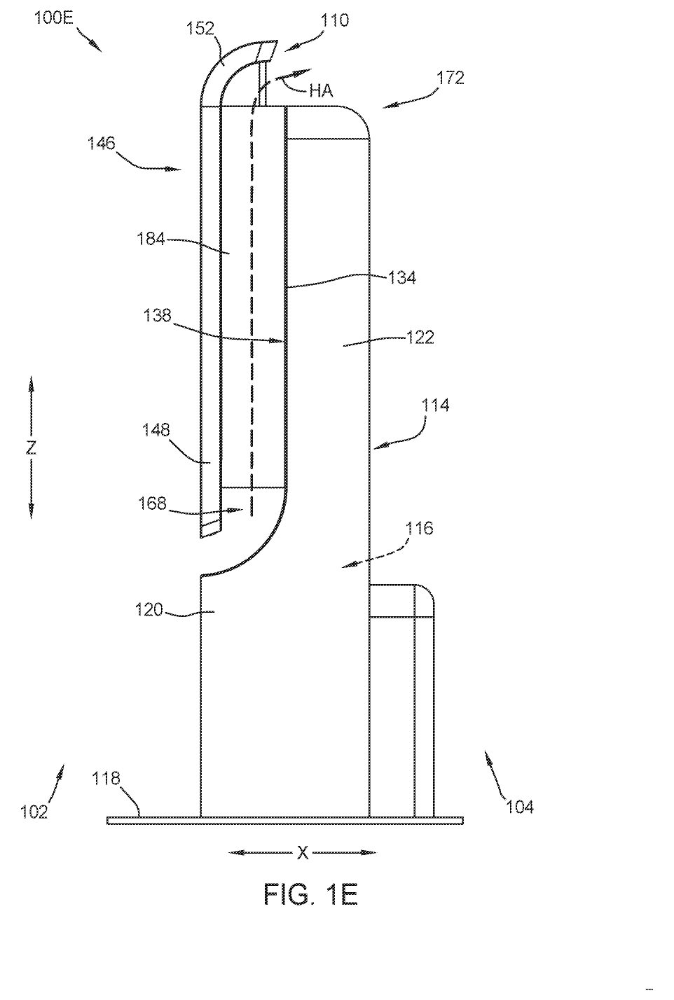

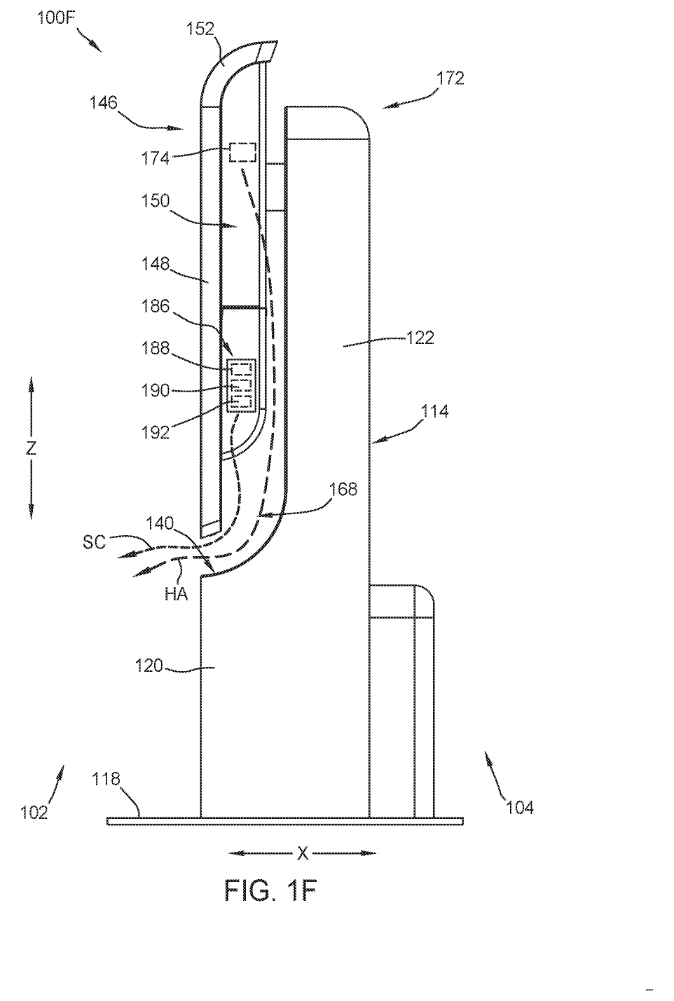

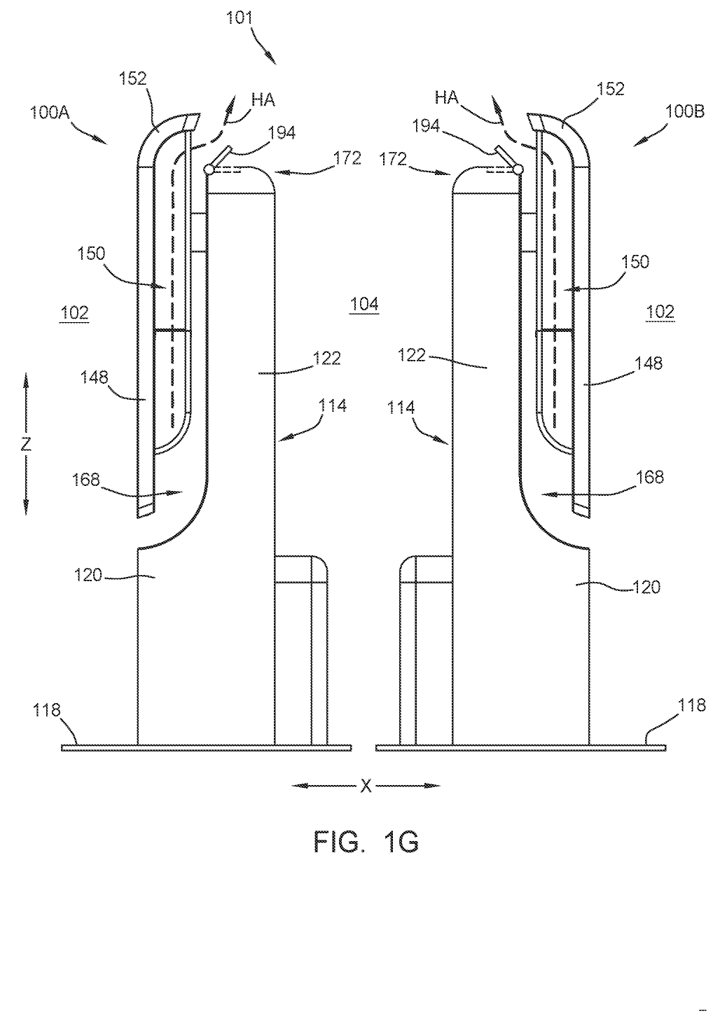

Turning now to the drawings, FIG. 1A depicts a perspective view of a self-checkout system 100, according to one or more aspects of the present disclosure. The self-checkout system 100 can also be referred to as a self-service kiosk or a checkout terminal. For reference, the self-checkout system 100 defines an X-direction, a Y-direction, and a Z-direction, which are mutually perpendicular to one another. In one or more examples, the X-direction is a transverse direction, the Y-direction is a lateral direction, and the Z-direction is a vertical direction.

The self-checkout system 100 has a front 102 and a back 104, a first side 106 and a second side 108, and a top side 110 and a bottom side 112. The self-checkout system 100 includes a housing 114, or cabinet, defining an interior 116 (FIG. 1B). The housing 114 has a base support 118, a base 120, and a back panel 122. The base 120 is seated on, and extends from, the base support 118, e.g., upward along the Z-direction. Various items can be disposed within the base 120, such as a printer 124 (FIG. 1B) and a scanner 126 (FIG. 1B), among other possible components. A front wall of the base 120 provides a printer dispenser 128 from which receipts and/or other items printed by the printer 124 can be dispensed. The front wall of the base 120 also provides a scanner window 130 to allow light from the scanner 126 to project onto items and for reflected rays to be captured by the scanner 126. In one or more examples, the self-checkout system 100 can also include one or more cameras, e.g., for capturing images of items, biometric data, etc.

The base support 118 extends around or circumscribes the base 120 and can be mounted, e.g., on a countertop, a shelf, a tower extending to the floor, etc. The base support 118 is generally planar and extends in a plane, e.g., perpendicular to the Z-direction, or rather, in an XY plane. In one or more examples, a base extension 132 can extend from the back of the base 120. The base extension 132 can provide an ingress/egress for cables and the like.

The back panel 122 extends upward from the base 120, e.g., along the Z-direction, and has a front wall 134 and a back wall 136. The front wall 134 has a vertically-oriented planar surface 138 and a curved bottom surface 140 that transitions the front wall 134 between a vertical orientation and a horizontal orientation. The vertically-oriented planar surface 138 and the curved bottom surface 140 can be contiguous. In at least one example, the back panel 122 can be integrally formed with the base 120 as a unitary monolithic component. In one or more other examples, the back panel 122 and the base 120 can be separate components coupled together. A payment terminal 142 can be mounted to a side wall of the back panel 122. The payment terminal 142 can include a display, keypad, a card reader, near field communication (NFC) beacon, etc. for facilitating payment processing during a transaction. In addition, a handheld scanner 144 can be mounted to the back panel 122.

With reference now to FIGS. 1A and 1B, FIG. 1B depicts a side view of the self-checkout system 100. As depicted, the self-checkout system 100 includes an interactive module 146 having a display screen 148, a control unit 150, and a curved deflector 152. The interactive module 146 is mounted to the back panel 122, such as to the vertically-oriented planar surface 138 of the front wall 134 by way of a mounting bracket 154. In at least some examples, the interactive module 146 is cantilevered from the vertically-oriented planar surface 138, e.g., as shown in FIG. 1B.

The display screen 148 can present information to a user, such as the cost of scanned items, whether an item is on sale or discounted, a weight of an item, etc. In one or more examples, the display screen 148 is a touchscreen, allowing users to provide inputs to the screen to make selections during a transaction. The display screen 148 has a top side 156 and a bottom side 158. The bottom side 158 has a beveled edge 160 that slopes upward from front to back. In one or more other examples, the bottom side 158 of the display screen 148 can have other suitable configurations, such as a chamfered edge. The display screen 148 extends a plane perpendicular to the X-direction, or rather, is arranged in a YZ plane. In one or more examples, the display screen 148 can be arranged between 1.5 to 2 inches (≈ 3.8 cm to 5.1 cm) from the vertically-oriented planar surface 138 of the front wall 134, including the endpoints. In one or more examples, the curved bottom surface 140 of the front wall 134 curves underneath the display screen 148, e.g., as shown in FIG. 1B. Moreover, as illustrated in FIG. 1B, the display screen 148 overhangs the base 120 of the housing 114, at least in part.

The control unit 150 has a casing 162 disposed along a back of the display screen 148. The casing 162 can have a curved bottom end and a top end that engages the curved deflector 152. The casing 162 can include one or more openings, vents, perforations, etc. at its top end to allow air to escape from an interior thereof. A plurality of components can be disposed within the casing 162. In at least one example, the control unit 150 can include a computing system 164 having one or more processors and one or more memory devices, such as one or more non-transitory memory devices. The one or more memory devices can store a program, which, when executed, causes the one or more processors to, individually or collectively, perform an operation. In at least one example, the operation can include controlling one or more controllable devices to control or manage the thermal load of the display screen 148, the control unit 150, and/or components of the self-checkout system 100 that produce heat during operation. The computing system 164 can be communicatively coupled with the display screen 148, the printer 124, the scanner 126, the payment terminal 142 (not shown in FIG. 1B; see FIG. 1A), the handheld scanner 144, as well as other controllable devices of the self-checkout system 100, e.g., by way of one or more wired and/or wireless communication links. The control unit 150 can also include a power supply for providing electrical power to the electrical power-consuming devices of the self-checkout system 100. The components of the computing system 164 can be disposed within the casing 162.

The control unit 150 can also include one or more sensors, such as one or more temperature sensors 166 (only one depicted in FIG. 1B). Sensor feedback from the temperature sensors 166 can be used to monitor the temperature of the display screen 148, components of the control unit 150, components within the base 120, and/or the temperature within an airflow channel 168 defined between the display screen 148 and the back panel 122. Sensor feedback can be provided to the computing system 164, e.g., so that the one or more processors can process the received data and perform operations, such as controlling the thermal load of the self-checkout system 100.

The curved deflector 152 is arranged at the top side 156 of the display screen 148. The curved deflector 152 has a lane light 170 facing the front 102 of the self-checkout system 100, as shown in FIG. 1A. The lane light 170 can indicate a status of the self-checkout system 100, e.g., ready for use, occupied, etc. In one or more other examples, the curved deflector 152 can include a camera, a speaker, and/or one or more other interactive devices. The curved deflector 152 has concave curvature with respect to the back panel 122. As shown in FIG. 1B, the curved deflector 152 curves “inward” with respect to a top end 172 of the back panel 122. In one or more examples, the curved deflector 152 is disposed, at least in part, vertically above the back panel 122 of the housing 114, e.g., as illustrated in FIG. 1B. Stated another way, at least a portion of the curved deflector 152 is at a greater height than the top end 172 of the back panel 122, e.g., along the Z-direction. In at least one example, the curved deflector 152 is disposed entirely vertically above the back panel 122 of the housing 114.

In one or more examples, the airflow channel 168 is formed between the interactive module 146 and the back panel 122 so that the air within the airflow channel 168 and heated by the display screen 148, one or more components of the control unit 150, and/or other components of the self-checkout system 100 travels upwards along the airflow channel 168 and is deflected away from the display screen 148 by the curved deflector 152. For instance, as shown in FIG. 1B, heat produced by the display screen 148, one or more components of the control unit 150, and/or other components of the self-checkout system 100 can be imparted to the air within the airflow channel 168. This heated air HA can rise or travel upwards along the airflow channel 168, and when the heated air HA reaches the top portion of the airflow channel 168, the curved deflector 152 deflects the heated air HA towards the back 104, or rather, away from the display screen 148 and the control unit 150.

Advantageously, the architecture of the self-checkout system 100 allows for heat produced by the display screen 148, one or more components of the control unit 150, and/or other components of the self-checkout system 100 to be transferred away, which can enhance the cooling of these components and thus can improve their performance and lifespans. Moreover, the curved deflector 152 can direct the heated air HA away from a user engaging in a transaction at the self-checkout system 100, which can enhance the shopping experience of the user.

In one or more examples, the heated air HA can travel upwards along the airflow channel 168 and can be deflected by the curved deflector 152 by natural convection. In this regard, the airflow channel 168 can function like a chimney to direct heat away from the display screen 148, one or more components of the control unit 150, and/or other components of the self-checkout system 100. The heated air HA, which can be less dense than the surrounding relatively cooler air, naturally rises to the top end of the airflow channel 168 and is deflected toward the back 104 of the self-checkout system 100 by way of the curved deflector 152, while less dense and relatively cooler air can circulate into the airflow channel 168 to provide cooling air to the display screen 148 and components of the control unit 150.

In one or more examples, the heated air HA can travel upwards along the airflow channel 168 and can be deflected by the curved deflector 152 by forced convection. For instance, as shown in FIG. 1B, the interactive module 146 has a fan 174 disposed on a back side of the display screen 148. The fan 174 is arranged to selectively move air upwards through the airflow channel 168. By way of example, the fan 174 can be selectively activated based at least in part on feedback indicating that a temperature threshold has been achieved, such as sensor feedback provided by the one or more temperature sensors 166.

In at least one example, the one or more processors of the computing system 164, in executing a program stored on one or more memory devices, perform, individually or collectively, an operation that includes receiving sensor feedback, e.g., from one or more of the temperature sensors 166. The operation also includes determining whether a temperature threshold has been achieved, based at least in part on the sensor feedback. In at least one example, this can include comparing a current temperature to the temperature threshold, with the current temperature being determined based on the sensor feedback. The operation further includes activating the fan 174 to move the heated air HA when the temperature threshold has been achieved. In activating the fan 174, the fan 174 can force the heated air HA to the top end of the airflow channel 168 so that the heated air HA can be expelled therefrom, e.g., generally toward the back 104 and away from the display screen 148 and the control unit 150. When activated, the fan 174 can run for a predetermined time or until a condition is met, such as when the current temperature no longer achieves the temperature threshold (e.g., by falling below the temperature threshold), and/or when a user is present at the self-checkout system 100.

In one or more further examples, the operation can include receiving data indicating whether a user is present at the self-checkout system 100. For instance, a camera of the self-checkout system 100 can capture whether a user is present at the self-checkout system 100, and this captured image data can be received by the one or more processors of the computing system 164. In such examples, the operation can include activating the fan 174 when no user is present at the self-checkout system 100. When the temperature threshold has been achieved but a user is in fact present at the self-checkout system 100, the one or more processors can deactivate or not activate the fan 174. The one or more processors can put a “hold” on the activation of the fan 174 until the user is no longer present at the self-checkout system 100. Such a control scheme can prevent the fan 174 from making noise while a user is present at the self-checkout system 100.

FIG. 1C depicts a side view of a self-checkout system, according to one or more aspects of the present disclosure. The self-checkout system 100C is configured in a similar manner as the self-checkout system 100 of FIGS. 1A and 1B, and thus, similar numerals will be used to refer to like structures in describing the self-checkout system 100C.

As shown in FIG. 1C, a top end 172 of the back panel 122 has a curved portion 176 shaped complementary to the curved deflector 152. The curved portion 176 of the back panel 122 can have a same radius as the inner surface of the curved deflector 152, or a similar radius (e.g., within fifteen degrees (15°) of each other). Advantageously, the complementary curved surfaces can further facilitate the travel of the heated air HA out of the airflow channel 168, including for heated air HA that is traveling upwards within the airflow channel 168 external to the casing 162 of the control unit 150.

Further, in one or more examples, the curved deflector 152 can overhang the back panel 122, at least in part. As shown in FIG. 1C, the curved deflector 152 overhangs the top end 172 of the back panel 122, at least in part. In this way, the top end 172 of the back panel 122 is arranged underneath, and spaced from, the curved deflector 152. The arrangement of the curved deflector 152, which, as noted, includes an extended portion overhanging the top end 172 of the back panel 122, and the top end 172 of the back panel 122 functions like a nozzle to expel heated air HA generally horizontally towards the back 104 of the self-checkout system 100C.

FIG. 1D depicts a side view of a self-checkout system 100D, according to one or more aspects of the present disclosure. The self-checkout system 100D is configured in a similar manner as the self-checkout system 100 of FIGS. 1A and 1B, and thus, similar numerals will be used to refer to like structures in describing the self-checkout system 100D.

As shown in FIG. 1D, in one or more examples, the housing 114 of the self-checkout system 100D includes one or more vents that provide fluid communication between the interior 116 of the housing 114 and the airflow channel 168. In at least one example, at least one vent of the one or more vents is disposed on the front wall 134 of the back panel 122. In the example depicted in FIG. 1D, the housing 114 has a first vent 178 arranged along the curved bottom surface 140 of the front wall 134, a second vent 180 arranged along the vertically-oriented planar surface 138 below the mounting bracket 154, and a third vent 182 arranged along the vertically-oriented planar surface 138 above the mounting bracket 154. In other examples, the housing 114 can have more or less than the vents depicted in FIG. 1D.

The first vent 178, the second vent 180, and the third vent 182 each provide fluid communication between the interior 116 of the housing 114 and the airflow channel 168. In this way, heat produced by one or more components disposed within the interior 116 can be transferred from the interior 116 to the airflow channel 168, and eventually expelled at the top end of the airflow channel 168. In the illustrated example in FIG. 1D, the heat produced by the scanner 126 and the printer 124, or heated air HA, is shown traveling upward through the interior 116 of the housing 114. A first portion of the heated air HA can escape the interior 116 into the airflow channel 168 by way of the first vent 178. A second portion of the heated air HA can escape the interior 116 into the airflow channel 168 by way of the second vent 180. Finally, a third portion of the heated air HA can escape the interior 116 into the airflow channel 168 by way of the third vent 182. The heated air HA from the interior 116 can join the air heated by the display screen 148 and components of the control unit 150 and travel upwards through the airflow channel 168, eventually being deflected by the curved deflector 152 and expelled at the top end of the airflow channel 168. The architecture of the self-checkout system 100D can thus provide an integrated heating approach, efficiently transferring heat produced by components within the housing 114 and heat produced by components of the interactive module 146 away from the self-checkout system 100D.

FIG. 1E depicts a schematic side view of a self-checkout system 100E, according to one or more aspects of the present disclosure. The self-checkout system 100E is configured in a similar manner as the self-checkout system 100 of FIGS. 1A and 1B, and thus, similar numerals will be used to refer to like structures in describing the self-checkout system 100E.

As shown in FIG. 1E, in one or more examples, the self-checkout system 100E can include side baffles 184 (only one shown in FIG. 1E) arranged at the sides of the airflow channel 168. In at least one example, the side baffles 184 can extend between the back side of the display screen 148 and the vertically-oriented planar surface 138 of the front wall 134, e.g., as shown in FIG. 1E. The side baffles 184 can provide barriers that prevent heat from escaping the sides of the airflow channel 168. Accordingly, the side baffles 184 can direct the heated air HA to the top end of the airflow channel 168 so that the heated air HA can be deflected toward the back 104 of the self-checkout system 100E.

In at least one example, the side baffles 184 can be arranged parallel to one another. In at least one example, the side baffles 184 can be arranged to converge toward one another as the side baffles extend toward the top side 110 of the self-checkout system 100E. In this regard, the converging side baffles 184 can expel heat from the airflow channel 168 from a more centrally located position, which can advantageously direct the heated air HA away from the self-checkout system 100E with enhanced precision.

In one or more further examples, the casing of the control unit 150 can include one or more internal baffles that guide airflow onto predetermined areas of the control unit 150, such as onto the one or more processors and/or power supply.

FIG. 1F depicts a schematic side view of a self-checkout system 100F, according to one or more aspects of the present disclosure. The self-checkout system 100E is configured in a similar manner as the self-checkout system 100 of FIGS. 1A and 1B, and thus, similar numerals will be used to refer to like structures in describing the self-checkout system 100F.

As shown in FIG. 1F, in one or more examples, the interactive module 146 of the self-checkout system 100F includes a scent emitter 186 having, among other things, a scent chamber 188 for storing one or more scents, a valve 190 (e.g., a solenoid valve) controllable to open and close the scent chamber 188, and a scent blower 192 or fan for moving a predetermined scent released from the scent chamber 188 by the valve 190. The scent emitter 186 is arranged to selectively emit a predetermined scent (e.g., a lavender scent, a peppermint scent, a pumpkin scent, a coffee scent, a vanilla scent, a chocolate scent, a pine scent, a fragrance or perfume, etc.) and the scent blower 192 thereof is arranged to selectively move the emitted predetermined scent downwards along the airflow channel 168 so that the curved bottom surface 140 deflects the predetermined scent toward the front 102 of the self-checkout system 100F, e.g., so as to urge the predetermined scent toward a user present at the self-checkout system 100F.

In at least one example, the one or more processors of the computing system 164, in executing a program stored on one or more memory devices, perform, individually or collectively, an operation that includes determining whether a trigger condition has been met, based at least in part on captured data. Example trigger conditions can include, without limitation, that a predetermined user is present at the self-checkout system 100F (e.g., a user that has indicated that they prefer that scents be emitted during a transaction), a user is purchasing a predetermined item (e.g., an item associated with an upcoming holiday), that a user is in a predetermined mood, etc. The data can be captured by one or more cameras of the self-checkout system 100F, by the scanner 126, etc. When the trigger condition is met, the operation can include opening the valve 190 to release the predetermined scent SC from the scent chamber 188. In addition, the operation can include activating the scent blower 192 to move the released predetermined scent SC, e.g., downwards along the airflow channel 168 so that the curved bottom surface 140 deflects the predetermined scent SC toward the front 102 of the self-checkout system 100F, e.g., as shown in FIG. 1F.

In one or more examples, the fan 174 of the self-checkout system 100F can be arranged to move heated air HA downward along the airflow channel 168 as shown in FIG. 1F. In at least one example, the fan 174 of the self-checkout system 100F can be arranged to move heated air HA downward along the airflow channel 168 as shown in FIG. 1F or upward along the airflow channel 168 (e.g., as shown in FIG. 1B), depending on one or more conditions. In one example, the self-checkout system 100F can be arranged near an ingress/egress to the outdoors, and the outdoor temperature can be relatively cold, such as below freezing. In such an example, based on the conditions of the outdoor temperature, the fan 174 can be activated to move heated air HA downward along the airflow channel 168 so that the curved bottom surface 140 deflects the heated air HA toward the front 102 of the self-checkout system 100F, e.g., toward a user present at the self-checkout system 100F to provide a warming effect and also to move the heat away from the display screen 148 and the control unit 150. In contrast, when the outdoor temperature is relatively warm, such as above freezing, the fan 174 can be activated to move heated air HA upward along the airflow channel 168 so that the curved deflector 152 deflects the heated air HA toward the back 104 of the self-checkout system 100F and away from the user, the display screen 148, and the control unit 150. Other conditions are contemplated, such as the indoor temperature, the scent emitted (e.g., when a pine or coffee scent is emitted), user preference, an item type being purchased, etc. When activated, the fan 174 can run for a predetermined time or until a condition is met.

FIG. 1G depicts a side view of a checkout area 101 having a plurality of self-checkout systems, according to one or more aspects of the present disclosure. As illustrated in FIG. 1G, the checkout area 101 includes at least a first self-checkout system 100A and a second self-checkout system 100B arranged back-to-back. The first self-checkout system 100A and the second self-checkout system 100B are both arranged in a similar manner as the self-checkout system 100 of FIGS. 1A and 1B, and thus, similar numerals will be used to refer to like structures in describing the first and second self-checkout systems 100A, 100B.

As depicted in FIG. 1G, the first self-checkout system 100A includes an adjustable baffle 194 disposed on the top end 172 of the back panel 122. The adjustable baffle 194 is movable between a retracted position and a deployed position. In FIG. 1G, the adjustable baffle 194 is shown in the deployed position, with the adjustable baffle 194 being shown in the retracted position in phantom lines. In at least one example, the adjustable baffle 194 can be hingedly coupled with the back panel 122, e.g., as shown in FIG. 1G. In one or more examples, the adjustable baffle 194 can be manually adjusted, e.g., by a user input. In one or more examples, the adjustable baffle 194 can be automatically adjusted, e.g., by a controllable motor coupled thereto. Further, in one or more examples, the adjustable baffle 194 can be adjustable to different deployed positions, such as to a fully deployed position and an intermediate deployed position, in addition to the retracted position. The adjustable baffle 194 can be oriented at a different angle relative to a reference axis in each one of the plurality of deployed positions.

In the retracted position, the adjustable baffle 194 is arranged to allow heated air deflected by the curved deflector 152 to flow unimpeded toward the back of the first self-checkout system 100A. However, in the deployed position, as shown in FIG. 1G, the adjustable baffle 194 is arranged to direct air deflected by the curved deflector 152 upwards, e.g., along the Z-direction. Accordingly, heated air flowing along the airflow channel 168 can first be deflected by the curved deflector 152 towards the back 104 of the first self-checkout system 100A and away from the display screen 148, and then, the deflected heated air can be deflected once again by the adjustable baffle 194 upwards, e.g., along the Z-direction. Advantageously, the adjustable baffle 194 directs the heated air upwards rather than straight horizontally to the back 104 so that the heated air is not moved directly toward the second self-checkout system 100B arranged back-to-back with the first self-checkout system 100A. Such an arrangement can enhance cooling of the first and second self-checkout systems 100A, 100B. Moreover, this arrangement can also prevent heated air from blowing directly onto a user using the second self-checkout system 100B, which can enhance the user’s shopping experience.

The second self-checkout system 100B also includes an adjustable baffle 194 disposed on the top end 172 of the back panel 122. The adjustable baffle 194 is movable between a retracted position and a deployed position. In FIG. 1G, the adjustable baffle 194 is shown in the deployed position, with the adjustable baffle 194 being shown in the retracted position in phantom lines. The adjustable baffle 194 of the second self-checkout system 100B is configured in a same manner as the adjustable baffle 194 of the first self-checkout system 100A, and consequently, the adjustable baffle 194 can be moved to the deployed position to direct air deflected by the curved deflector 152 upwards, e.g., along the Z-direction. Thus, heated air flowing along the airflow channel 168 can first be deflected by the curved deflector 152 towards the back 104 of the second self-checkout system 100B and away from the display screen 148, and then, the deflected heated air can be deflected once again by the adjustable baffle 194 upwards, e.g., along the Z-direction. Advantageously, the adjustable baffle 194 directs the heated air upwards rather than straight horizontally to the back 104 so that the heated air is not moved directly toward the first self-checkout system 100A. Such an arrangement can enhance cooling of the first and second self-checkout systems 100A, 100B. Moreover, this arrangement can also prevent heated air from blowing directly onto a user using the first self-checkout system 100A, which can enhance the user’s shopping experience.

The features shown in FIGS. 1A, 1B, 1C, 1D, 1E, 1F, 1G and described in the accompanying text are combinable with one another, and any combination of these features is contemplated. For instance, in at least one example, the features of FIGS. 1A and 1B can be combined with the features of FIG. 1C, or the features of FIG. 1D, or the features of FIG. 1E, or the features of FIG. 1F, or the features of FIG. 1G, or any combination thereof.

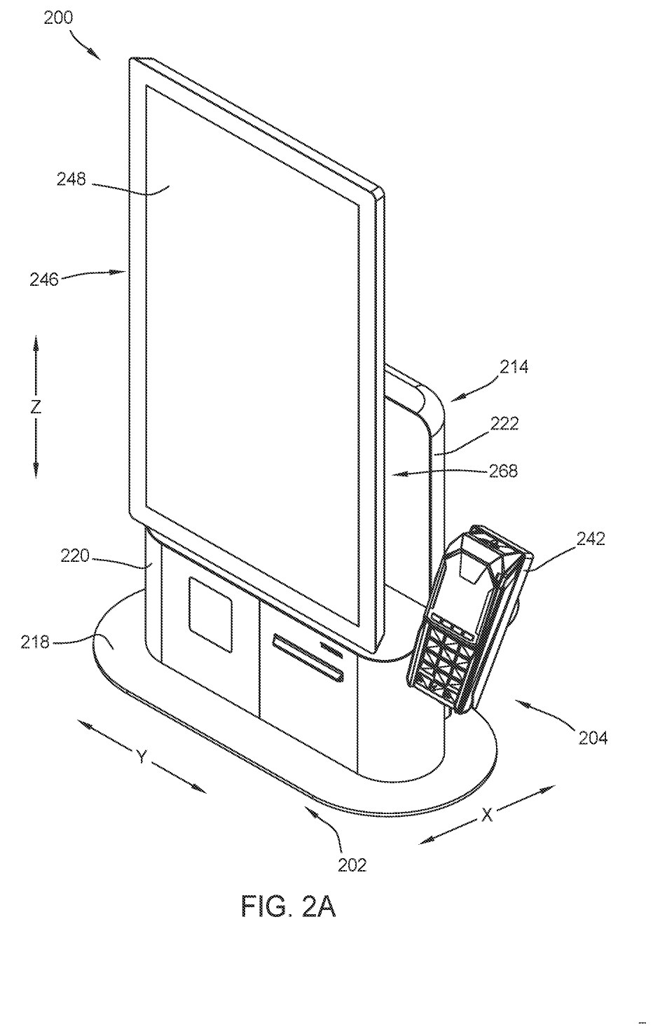

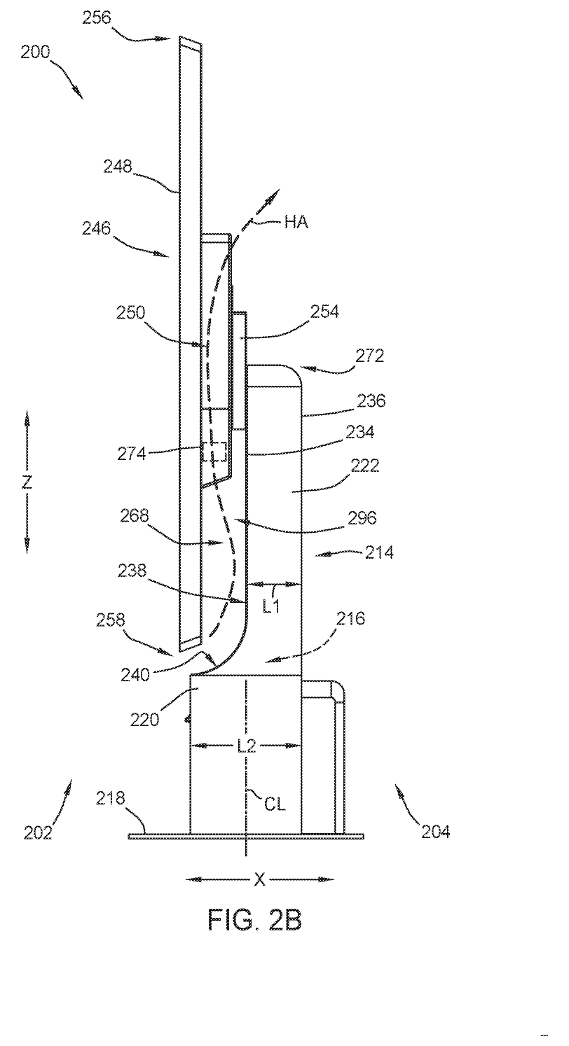

With reference now to FIGS. 2A and 2B, FIG. 2A depicts a perspective view of a self-checkout system 200, according to one or more aspects of the present disclosure. FIG. 2B depicts a side view of the self-checkout system 200. The self-checkout system 200 is configured in a similar manner as the self-checkout system 100 of FIGS. 1A and 1B, and thus, similar numerals will be used to refer to like structures in describing the self-checkout system 200, except that the numerals are each increased by one hundred.

As shown in FIGS. 2A and 2B, the self-checkout system 200 has a front 202 and a back 204, and includes a housing 214, or cabinet, defining an interior 216. The housing 214 has a base support 218, a base 220, and a back panel 222. The back panel 222 extends upward from the base 220, e.g., along the Z-direction, and has a front wall 234 and an opposing back wall 236. The front wall 234 has a vertically-oriented planar surface 238 and a curved bottom surface 240 that transitions the front wall 234 between a vertical orientation and a horizontal orientation. The back panel 222 has a top end 272. A payment terminal 242 can be mounted to a side wall of the back panel 122.

The self-checkout system 200 further includes an interactive module 246 having a display screen 248 and a control unit 250. The interactive module 246 is mounted to the back panel 222, such as to the vertically-oriented planar surface 238 of the front wall 234 by way of a mounting bracket 254. In at least some examples, the interactive module 246 is cantilevered from the vertically-oriented planar surface 238, e.g., as shown in FIG. 2B. The mounting bracket 254 can couple the interactive module 246, or a casing of the control unit 250, with the back panel 222 at the top end 272 of the back panel 222. Moreover, in this example, the display screen 248 extends vertically above the top end 272 of the back panel 222. In at least one example, at least half of a vertical length of the display screen 248 is arranged vertically above the top end 272 of the back panel 222. In the example depicted in FIG. 2B, more than half the vertical length of the display screen 248 is arranged vertically above the top end 272. The vertical length of the display screen 248 extends between a top side 256 and a bottom side 258, e.g. along the Z-direction.

An airflow channel 268 is defined between the display screen 248 and the back panel 222. Heated air HA, or air to which heat produced by the display screen 248 and the control unit 250 has been imparted, can travel upwards along the airflow channel 268 by natural convection or forced convection by way of a fan 274. The heated air HA can be expelled generally toward the back 204 of the self-checkout system 200. In comparison to the self-checkout system 100 of FIGS. 1A, 1B, the self-checkout system 200 does not include a curved deflector in the example of FIGS. 2A and 2B, but could in one or more other examples. Accordingly, the self-checkout system 200 in the example of FIGS. 2A and 2B utilizes the height of the display screen 248 to maintain the heated air HA toward the back 204 of the self-checkout system 200. In one or more further examples, the fan 274 can be activated to move the heated air HA downward along the airflow channel 268 depending on the conditions, much like in the example described with respect to FIG. 1F.

In one or more examples, the architecture of the self-checkout system 200 can enable the center of gravity of the system to be centrally located, which can advantageously reduce the stress on the mounting bracket 254 and the back panel 222, can make the self-checkout system 200 less susceptible to tipping, e.g., in the event the self-checkout system 200 is subject to an impact event, can provide users with a more solid feel when providing an input to the display screen 248, and can make the design more compact.

As shown in FIGS. 2A and 2B, in one or more examples, a transverse length L1 of the back panel 222 (e.g., a length of the back panel 222 along the X-direction from the vertically-oriented planar surface 238 of the front wall 234 to the back wall 236) is less than or equal to half a transverse length L2 of the base 220 (e.g., a length of the base 220 along the X-direction extending between a forward wall and a rear wall of the base 220, as shown in FIG. 2B). In this regard, the housing 214 forms a cutout 296 or area in which the interactive module 246, including the display screen 248 and the control unit 250, can be arranged. The cutout 296 provides a space for the display screen 248 to overhang the base 220 of the housing 214, at least in part, e.g., as illustrated in FIG. 2B. This allows for the display screen 248 and the control unit 250 to be arranged closer to a transverse centerline CL of the self-checkout system 200, which can enable the center of gravity of the self-checkout system 200 to be more centrally located. As noted above, centrally locating the center of gravity can have various benefits and advantages.

Further, the radiused bottom end of the back panel 222 that couples with the base 220 at the forward side of the housing 214 can provide structural rigidity to the back panel 222, which facilitates the mounting of the interactive module 246 to the back panel 222 and can reduce stress concentrations within the housing 214. As shown in FIG. 2B, the back panel 222 increases in transverse length according to the radius of the curved bottom surface 240 at its radiused bottom end. The curved bottom surface 240 curves underneath the display screen 248.

It will be appreciated that the housing of the self-checkout systems of FIGS. 1A, 1B, 1C, 1D, 1E, 1F, 1G each have a same or similar configuration as the self-checkout system 200. Accordingly, the architecture of the self-checkout systems of FIGS. 1A, 1B, 1C, 1D, 1E, 1F, 1G can enable the center of gravity of these systems to be centrally located, which can provide the advantages noted above.

In addition, it is contemplated that any of the features shown in FIGS. 1A, 1B, 1C, 1D, 1E, 1F, 1G and described in the accompanying text can be implemented in the self-checkout system 200 of FIGS. 2A, 2B, and in any combination.

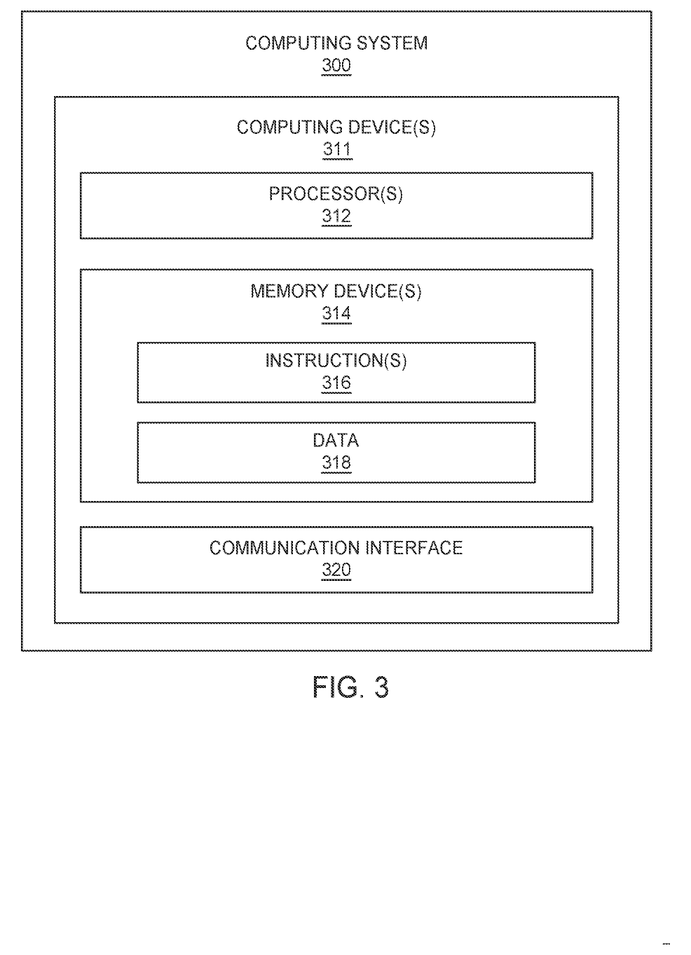

FIG. 3 is a block diagram of a computing system 300 for a self-checkout system, according to one or more aspects of the present disclosure. For instance, the computing system of any of the self-checkout systems described herein can be arranged according to the computing system 300 of FIG. 3.

As shown in FIG. 3, the computing system can include one or more processor(s) 312 and one or more memory device(s) 314, which can be embodied in one or more computing device(s) 311. The one or more processor(s) 312 can include any suitable processing device, such as a microprocessor, microcontroller, integrated circuit, logic device, or other suitable processing device. The one or more memory device(s) 314 can include one or more computer-readable medium, including, but not limited to, non-transitory computer-readable medium, RAM, ROM, hard drives, flash drives, and other memory devices.

The one or more memory device(s) 314 can store information accessible by the one or more processor(s) 312, including computer-readable instructions 316 or computer-readable program code that can be executed by the one or more processor(s) 312. The instructions 316 can be any set of instructions that when executed by the one or more processor(s) 312, cause the one or more processor(s) 312 to perform an operation. The instructions 316 can be software written in any suitable programming language or can be implemented in hardware.

The memory device(s) 314 can further store data 318 that can be accessed by the processors 312. For example, the data 318 can include any of the data noted herein. The data 318 can include one or more table(s), function(s), algorithm(s), model(s), equation(s), libraries, etc. according to example aspects of the present disclosure.

The computing system 300 can also include a communication interface 320 used to communicate, for example, with the other components of a self-checkout system. The communication interface 320 can include any suitable components for interfacing with one or more network(s), including for example, transmitters, receivers, ports, controllers, antennas, or other suitable components.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to the described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not an advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

Aspects of the described embodiments may take the form of an entirely hardware embodiment, an entirely software embodiment (including firmware, resident software, micro-code, etc.) or an embodiment combining software and hardware aspects that may generally be referred to herein as a “circuit,” “module” or “system.”

One or more of the described embodiments may be a system, a method, and/or a computer program product. The computer program product may include a computer readable storage medium (or media) having computer readable program instructions thereon for causing a processor to carry out aspects of the embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the described embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the "C" programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the described embodiments.

Aspects of the described embodiments are described herein with reference to flowchart illustrations and/or block diagrams of methods, apparatus (systems), and computer program products according to embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a described manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to one or more embodiments, other and further embodiments may be devised without departing from the basic scope thereof, and the scope thereof is determined by the claims that follow.

What is claimed is:

1. A self-checkout system, comprising:
a housing having a base and a back panel extending from the base; and
an interactive module mounted to the back panel, the interactive module having a display screen and a curved deflector arranged at a top side of the display screen,
wherein an airflow channel is formed between the display screen and the back panel so that air within the airflow channel and heated by the display screen travels upwards along the airflow channel and is deflected away from the display screen by the curved deflector.

2. The self-checkout system of claim 1, wherein the back panel has a front wall having a vertically-oriented planar surface and a curved bottom surface that transitions the front wall between a vertical orientation and a horizontal orientation.

3. The self-checkout system of claim 2, wherein the interactive module is cantilevered from the vertically-oriented planar surface.

4. The self-checkout system of claim 2, wherein the curved bottom surface curves underneath the display screen.

5. The self-checkout system of claim 2, wherein the display screen overhangs the base of the housing at least in part.

6. The self-checkout system of claim 1, wherein the interactive module has a fan disposed on a back side of the display screen arranged to selectively move air upwards through the airflow channel.

7. The self-checkout system of claim 6, wherein the fan is selectively activated based at least in part on feedback indicating that a temperature threshold has been reached.

8. The self-checkout system of claim 1, wherein the curved deflector has concave curvature with respect to the back panel.

9. The self-checkout system of claim 1, wherein a curved deflector is vertically above the back panel of the housing.

10. The self-checkout system of claim 1, wherein a top end of the back panel has a curved portion shaped complementary to the curved deflector.

11. The self-checkout system of claim 1, wherein curved deflector overhangs the back panel at least in part.

12. The self-checkout system of claim 1, wherein the housing has one or more vents that provide fluid communication between an interior of the housing and the airflow channel.

13. The self-checkout system of claim 12, wherein at least one vent of the one or more vents is disposed on a forward wall of the back panel.

14. The self-checkout system of claim 1, further comprising:
an adjustable baffle disposed on a top side of the back panel, the adjustable baffle being movable between a retracted position and a deployed position, and wherein, in the deployed position, the adjustable baffle is arranged to direct air deflected by the curved deflector upwards.

15. A self-checkout system, comprising:
a housing having a base and a back panel extending from the base;
an interactive module mounted to the back panel, the interactive module having a display screen, wherein an airflow channel is formed between the display screen and the back panel;
a fan; and
a computing system having one or more processors and one or more memory devices storing a program, which, when executed, causes the one or more processors to, individually or collectively, perform an operation, comprising:
receiving an input indicating a current temperature;
determining whether a temperature threshold has been achieved based at least in part on the current temperature; and
activating, when the temperature threshold has been achieved, the fan to move heated air within the airflow channel upwards or downwards along the airflow channel.

16. The self-checkout system of claim 15, wherein the operation further comprises:
determining whether a user is present at the self-checkout system,
wherein the fan is deactivated or not activated when the user is present at the self-checkout system.

17. The self-checkout system of claim 15, wherein the interactive module includes a scent emitter having a scent chamber and a scent blower, and wherein the operation further comprises:
activating the scent blower to move a predetermined scent, which has been released from the scent chamber, along the airflow channel so that a curved bottom surface of the back panel deflects the predetermined scent toward a front of the self-checkout system.

18. A self-checkout system, comprising:
a housing, comprising:
a base; and
a back panel extending from the base, the back panel has a front wall and a back wall, the front wall having a vertically-oriented planar surface,
wherein the back panel has a transverse length extending between the vertically-oriented planar surface and the back wall and the base has a transverse length extending between a forward wall and a rear wall, and wherein the transverse length of the back panel is less than the transverse length of the base so that the housing defines a cutout; and
an interactive module mounted to the back panel, the interactive module having a display screen arranged in the cutout and overhanging, at least in part, the base.

19. The self-checkout system of claim 18, wherein the forward wall of the back panel has a curved bottom surface that transitions the front wall between a vertical orientation and a horizontal orientation, and wherein curved bottom surface is arranged underneath the display screen.

20. The self-checkout system of claim 18, wherein the interactive module is mounted to a top end of the back panel and at least half a vertical length of the display screen is arranged vertically above the top end.
